(19) United States
(12) Patent Application Publication
(10) Pub. No.: US 2024/0059946 A1
(43) Pub. Date: Feb. 22, 2024

(54) THERMAL INTERFACE MATERIAL

(71) Applicants: DOW GLOBAL TECHNOLOGIES LLC, Midland, MI (US); DOW SILICONES CORPORATION, Midland, MI (US)

(72) Inventors: Chao HE, Shanghai (CN); Dorab BHAGWAGAR, Auburn, MI (US); Jiguang ZHANG, Shanghai (CN); Ling LING, Shanghai (CN); Hongyu CHEN, Shanghai (CN); Peng WEI, Shanghai (CN); Yan ZHENG, Shanghai (CN); Chen CHEN, Shanghai (CN)

(73) Assignees: DOW GLOBAL TECHNOLOGIES LLC, Midland, MI (US); DOW SILICONES CORPORATION, Midland, MI (US)

(21) Appl. No.: 18/267,830

(22) PCT Filed: Dec. 24, 2020
(86) PCT No.: PCT/CN2020/138821

§ 371 Date: Jun. 16, 2023

(51) Int. Cl. C09K 5/06

(52) U.S. Cl. CPC C09K 5/06

(57) ABSTRACT

A thermal interface material is provided. The thermal interface material comprises: (A) a polyolefin having at least two hydroxy groups per molecule; (B) at least one thermally conductive filler; (C) a phase change material with a melting point of 25 to 150° C.; and (D) a coupling agent. A content of component (B) is at least 80 mass %, a content of component (C) is 0.01 to 1 mass %, and a content of component (D) is 0.1 to 1 mass %, each based on a total mass of the thermal interface material. The thermal interface material becomes softer as its temperature increases. Meanwhile, the thermal interface material generally does not exhibit pumping-out in electronic devices during power cycling.

### TECHNICAL FIELD

The present invention relates to a thermal interface material.

### BACKGROUND ART

Thermal interface materials (TIMs) are thermally conductive materials useful for heat transfer between two components in electronic devices. For example, TIMs are typically used to transfer heat from heat generating electronic components such as central processing units (CPU), or graphic processing units (GPU) to heat spreader such as a heat sink. Recently, the heat generating electronic components use increased power, have increased functionality requiring higher heat dissipation. And it is a trend to use bare die design for applications like GPU and Al chips. Therefore, a thermal impedance (TI) of TIMs it is desirable to have a value of less than 0.1° C.·cm²/W.

TIMs for heat transfer in electronic devices are well known in the art. For example, Patent Document 1 describes a thermally conductive material comprising: (a) 100 parts by weight of wax, (b) 10 to 1,000 parts by weight of a liquid polymer such as polyisobutylene, (c) 10 to 2,000 parts by weight of a thermally conductive filler, and (d) 0 to 1,000 parts by weight of a softener.

Patent Document 2 describes a thermal interface material comprising: at least one polymer, at least one thermally conductive filler, and at least one phase change material, wherein the at least one phase change material includes a wax having a needle penetration value of at least 50 as determined at 25° C. according to ASTM D 1321.

Patent Document 3 describes a thermal interface material comprising: at least one phase change material, at least one polymer matrix material, at least one first thermally conductive filler having a first particle size, and at least one second thermally conductive filler having a second particle size.

Patent Document 4 describes a thermally conductive composition comprising: a thermally conductive filler and a binder constituted from a phase change material having a melting point of 35-120° C., a non-ionic surfactant and a non-volatile component, wherein the content of the phase change material is 10 parts by mass or higher, the content of the non-ionic surfactant is 60 parts by mass or higher and the content of the non-volatile component is 30 parts by mass or less, each relative to 100 parts by mass of the binder.

However, TIMs typically pump-out and separate from two components in electronic devices during power cycling, particularly when the two components have different coefficients of thermal expansion. Bare die design can lead to large amount of pump-out as TIMs are directly applied between Integrated Circuit (IC) and a metal heat sink. Pump-out leads to increased bulk thermal resistance and increased interfacial resistance. For high-end applications, such a change in both the bulk and interfacial resistance is unacceptable due to the resulting dramatic production in performance. TIMs should also be stable to pump-out with power cycling in bare die design such as GPU or Al chip. TIMs should show minimal pump-out, less than 5%, after at least 5000 power cycles.

### PRIOR ART DOCUMENTS

### Patent Documents

Patent Document 1: International Publication No. WO2003/004580 A1

Patent Document 2: International Publication No. WO2015/120773 A1

Patent Document 3: International Publication No. WO2016/086410 A1

Patent Document 4: International Publication No. WO2016/185936 A1

### SUMMARY OF INVENTION

### Technical Problem

An object of the present invention is to provide a thermal interface material which becomes softer as its temperature increases, while it is not pumping-out in electronic devices during power cycling.

### Solution to Problem

The thermal interface material of the present invention comprises:
(A) a polyolefin having at least two hydroxy groups per molecule;
(B) at least one thermally conductive filler;
(C) a phase change material with a melting point of 25 to 150° C.; and
(D) a coupling agent,
wherein a content of component (B) is at least 80 mass %, a content of component (C) is 0.01 to 1 mass %, and a content of component (D) is 0.1 to 1 mass %, each based on a total mass of the present thermal interface material.

In various embodiments, component (A) is a polyolefin represented by the following general formula:

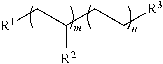

wherein each R¹, R² and R³ is independently a hydrogen atom, hydroxy group or an alkyl group with 1 to 12 carbons, providing that at least two of a total R¹ to R³ are the hydroxy groups; and “m” is a positive number, “n” is 0 or a positive number, provided that “m+n” is a positive number satisfying a number average molecular weight of 2,000 to 100,000 as measured by a gel permeation chromatography.

In various embodiments, component (B) is at least one thermally conductive filler selected from alumina, aluminum, zinc oxide, boron nitride, aluminum nitride, or aluminum oxide trihydrate.

In various embodiments, component (C) is at least one phase change material selected from C₁₂-C₂₅ alcohols, C₁₂-C₂₅ acids, C₁₂-C₂₅ esters, waxes, or combinations thereof.

In various embodiments, component (D) is at least one coupling agent selected from a silicon-based coupling agent, a titanium-based coupling agent, or an aluminum-based coupling agent.

In various embodiments, component (D) is a silicon-based coupling agent represented by the following general formula:

R⁴ₐR⁵_{b}Si(OR⁶)_{(4-a-b)}
wherein each R⁴ is independently an alkyl group with 6 to 15 carbons, each R⁵ is independently an alkyl group with 1 to 5 carbons or an alkenyl groups with 2 to 6 carbons, each R⁶ is independently an alkyl group with 1 to 4 carbons; and “a” is an integer of 1 to 3, “b” is an integer of 0 to 2, provided that “a+b” is an integer of 1 to 3.

In various embodiments, the thermal interface material further comprises: (E) an antioxidant.

In various embodiments, the thermal interface material further comprises: (F) a filler-to-polymer interaction promoter.

In various embodiments, component (F) is at least one filler-to-polymer interaction promoter selected from a liquid polybutadiene, a silane grafted polyolefin or a bis(trialkoxysilylalkyl)amine.

In various embodiments, the thermal interface material further comprises: (G) a solvent.

### Effects of Invention

The thermal interface material of the present invention becomes softer as its temperature increases, while it is not pumping-out in electronic devices during power cycling.

### Definitions

The terms “comprising” or “comprise” are used herein in their broadest sense to mean and encompass the notions of “including,” “include,” “consist(ing) essentially of,” and “consist(ing) of.” The use of “for example,” “e.g.,” “such as,” and “including” to list illustrative examples does not limit to only the listed examples. Thus, “for example” or “such as” means “for example, but not limited to” or “such as, but not limited to” and encompasses other similar or equivalent examples. The term “about” as used herein serves to reasonably encompass or describe minor variations in numerical values measured by instrumental analysis or as a result of sample handling. Such minor variations may be in the order of ±0-25, ±0-10, ±0-5, or ±0-2.5, % of the numerical values. Further, the term “about” applies to both numerical values when associated with a range of values. Moreover, the term “about” may apply to numerical values even when not explicitly stated.

The terms “thermal impedance” or “TI” are used herein to mean the efficacy of the TIM. The thermal impedance of the TIM between substrates are calculated by the following expression:

Θ=(d/κ)+R_{contact}
where Θ is thermal impedance of the TIM, d is the bond line thickness (BLT), κ is the thermal conductivity of the TIM and R_{contact} is the sum of contact resistance values of the TIM and adjoining substrates.

### DETAILED DESCRIPTION OF THE INVENTION

The thermal interface material of the present invention will be explained in detail.

Component (A) is a matrix material to disperse component (B), and is a polyolefin having at least two hydroxy groups per molecule. Exemplary polyolefins for component (A) include polyethylenes, polypropylenes, polyisobutylenes, ethylene-propylene copolymers, ethylene-isobutylene copolymers, ethylene-butylene-styrene copolymer; and hydrogenated polymers such as hydrogenated polyalkyldiene poly-ols (including hydrogenated polybutadiene poly-ol, hydrogenated polypropadiene poly-ol, and hydrogenated polypentadiene mono-ol), and hydrogenated polyalkyldiene diols (including hydrogenated polybutadiene diol, hydrogenated polypropadiene diol, and hydrogenated polypentadiene diol).

Among them, component (A) is preferably a polyolefin represented by the following general formula:

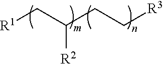

In the formula above, each R¹, R² and R³ is independently a hydrogen atom, hydroxy group or an alkyl group with 1 to 12 carbons, providing that at least two of a total R¹ to R³ are the hydroxy groups. Examples of the alkyl groups in the formula above include methyl groups, ethyl groups, propyl groups, isopropyl groups, butyl groups, isobutyl groups, tert-butyl groups, pentyl groups, neopentyl groups, hexyl groups, cyclohexyl groups, heptyl groups, octyl groups, nonyl groups, decyl groups, undecyl groups, and dodecyl groups;

In the formula above, “m” is a positive number, “n” is 0 or a number, however, “m+n” is a positive number satisfying a number average molecular weight of 2,000 to 100,000, preferably 3,000 to 100,000, as measured by a gel permeation chromatography.

The state of component (A) at 25° C. is not limited, but it is preferably a solid. Component (A) preferably has a melt viscosity, e.g., a melt viscosity at 45° C. of 1 to 100 Pa·s. Note that in the present specification, viscosity may be measured in accordance with JIS K7117-1: Plastics—Resins in the liquid state or as emulsions or dispersions—Determination of apparent viscosity by the Brookfield Test method, or ISO 2555: Plastics Resins in the Liquid State or as Emulsions or Dispersions Determination of Apparent Viscosity by the Brookfield Teste Method.

An exemplary commercially available polyolefin is NISSO-PB GI-3000, available from Nippon Soda Co., Ltd.

Component (B) is at least one thermally conductive filler which can be any useful in TIMs. For instance, component (B) can be any one or any combination of more than one thermally conductive filler selected from metals, alloys, nonmetals, metal oxides, or ceramics. Exemplary metals include but are not limited to aluminum, copper, silver, zinc, nickel, tin, indium, and lead. Exemplary nonmetals include but are not limited to carbon, graphite, carbon nanotubes, carbon fibers, graphenes, and silicon nitride. Exemplary metal oxides and ceramics include but are not limited to alumina, aluminum nitride, boron nitride, zinc oxide, and tin oxide. Desirably, component (B) is any one or any combination of more than one selected from a group consisting of alumina, aluminum, zinc oxide, boron nitride, aluminum nitride, and aluminum oxide trihydrate. Even more desirably, component (B) is any one or any combination or more than one filler selected from spherical aluminum particles having an average size of 5 to 15 μm, spherical aluminum particles having an average particle size of 1 to 3 μm, zinc oxide particles having an average particle size of 0.1 to 0.5 μm. Determine average particle size for filler particles as the median particle size (D50) using laser diffraction particle size analyzers (CILAS920 Particle Size Analyzer or Beckman Coulter LS 13 320 SW) according to an operation software.

The amount of component (B) is at least 80 mass %, preferably 85 mass % or more, even 90 mass % or more while at the same time is typically 95 mass % or less, 94 mass % or less, even 93 mass % or less with mass % relative to the total mass of the present thermally interface material.

Component (C) is a phase change material that undergoes a reversible solid-liquid phase change at operating temperatures of electronic devices. Component (C) has a melting point of 25 to 150° C., preferably 25 to 100° C., 25 to 80° C., alternatively 25 to 70° C. When cooled below its melting point, component (C) solidifies without a significant change in volume, thereby maintaining intimate contact between heat generating electronic components and heat spreader. Note that in the present specification, melting point (° C.) may be measured by a Differential Scanning calorimeter (DSC) in accordance with ASTM D3418.

Exemplary phase change materials for component (C) include C₁₂-C₂₅ alcohols, C₁₂-C₂₅ acids, C₁₂-C₂₅ esters, waxes, and combinations thereof. Suitable C₁₂-C₂₅ acids and alcohols include myristyl alcohol, 1,2-tetradecanediol, cetyl alcohol, stearyl alcohol, 1-eicosanol, pentacosanol, myristyl acid, and stearic acid. Preferred waxes include microcrystalline wax, paraffin waxes, and other wax-like C₁₈-C₄₀ olefins, such as octadecane, nonadecane, eicosane, heneicosane, docosane, tricosane, triacontane, and hexatriacontane.

The amount of component (C) is in a range of from 0.01 to 1 mass % of the present thermal interface material. However, it is desirably 0.05 mass % or more, 0.15 mass % or more, even 0.2 mass % or more while at the same time is typically 2.0 mass % or less, 1.5 mass % or less, 1.0 mass % or less, even 0.5 mass % or less based on the mass of the present thermal interface material. This is because when the content of component (C) is equal to or greater than the lower limit of the range described above, handleability of the present material are good, whereas when the content of component (D) is equal to or less than the upper limit of the range described above, physical properties of the present material are good.

Component (D) is a coupling agent and is useful to assist dispersing of component (B) in component (A). Component (D) is not limited, but it is preferably a silicon-based coupling agent, a titanium-based coupling agent, or an aluminum-based coupling agent.

The silicon-based coupling agent is preferably an alkoxysilane compound represented by the following general formula:

R⁴ₐR⁵_{b}Si(OR⁶)_{(4-a-b)}

In the formula, R⁴ is independently an alkyl group with 6 to 15 carbons. Exemplary alkyl groups include hexyl groups, heptyl groups, octyl groups, nonyl groups, decyl groups, undecyl groups, and dodecyl groups.

In the formula, R⁵ is independently an alkyl group with 1 to 5 carbons or an alkenyl groups with 2 to 6 carbons. Exemplary alkyl groups include methyl groups, ethyl groups, propyl groups, isopropyl groups, butyl groups, isobutyl groups, tert-butyl groups, pentyl groups, and neopentyl groups. Exemplary alkenyl groups include vinyl group, ally group, butenyl groups, pentenyl groups and hexenyl groups.

In the formula, R⁶ is independently an alkyl group with 1 to 4 carbons. Exemplary alkyl groups include methyl groups, ethyl groups, propyl groups, isopropyl groups, butyl groups, isobutyl groups, and tert-butyl groups.

In the formula, “a” is an integer of 1 to 3, “b” is an integer of 0 to 2, provided that “a+b” is an integer of 1 to 3, alternatively “a” is 1, “b” is an integer of 0 or 1, or alternatively “a” is 1, “b” is 0.

Exemplary silicon-based coupling agents for component (D) include hexyl trimethoxysilane, heptyl trimethoxysilane, octyl triethoxysilane, decyl trimethoxysilane, dodecyl trimethoxysilane, dodecyl methyl dimethoxysilane, dodecyl triethoxysilane, tetradecyl trimethoxysilane, octadecyl trimethoxysilane, octadecyl methyl dimethoxysilane, octadecyl triethoxysilane, nonadecyl trimethoxysilane, and any combination of at least two thereof.

Exemplary titanium-based coupling agents for component (D) include isopropyltriisostearoyl titanate, isopropyltris(dioctylpyrophosphate) titanate, isopropyltri(N-amidoethyl, aminoethyl) titanate, tetraoctylbis(ditridecylphosphate) titanate, tetra(2,2-diallyloxymethyl-1-butyl) bis(ditridecyl)phosphate titanate, bis(dioctylpyrophosphate)oxyacetate titanate, bis(dioctylpyrophosphate)ethylene titanate, isopropyltrioctanoyl titanate, isopropyidimethacrylisostearoyl titanate, isopropyltridodecylbenzenesulfonyl titanate, isopropylisostearoyidiacryl titanate, isopropyltri(dioctylphosphate) titanate, isopropyltricumylphenyl titanate, and tetraisopropylbis(dioctylphosphite) titanate.

Exemplary aluminum-based coupling agents for component (D) include alkylacetoacetate aluminum di-isopropylate.

The amount of component (D) is in a range from 0.1 to 1 mass % of the present thermal interface material. However, it is desirably 0.2 mass % or more, 0.3 mass % or more, even 0.5 mass % or more while at the same time is typically 3.0 mass % or less, 2.5 mass % or less, 2.0 mass % or less, even 1.0 mass % or less based on the mass of the present thermal interface material. This is because when the content of component (D) is equal to or greater than the lower limit of the range described above, dispersing of component (B) in the present thermal interface material is good, whereas when the content of component (D) is equal to or less than the upper limit of the range described above, stability of the present thermal interface material is good.

The present thermal interface material may further comprise (E) an antioxidant. Exemplary antioxidants for component (E) include hindered phenols such as tetrakis[methylene(3,5-di-tert-butyl-4-hydroxyhydro-cinnamate)]methane; bis[(beta-(3,5-ditert-butyl-4-hydroxybenzyl) methylcarboxyethyl)]-sulphide, 4,4′-thiobis(2-methyl-6-tert-butylphenol), 4,4′-thiobis(2-tert-butyl-5-methylphenol), 2,2′-thiobis(4-methyl-6-tert-butylphenol), and thiodiethylene bis(3,5-di-tert-butyl-4-hydroxy)-hydrocinnamate; phosphites and phosphonites such as tris(2,4-di-tert-butylphenyl)phosphite and di-tert-butylphenyl-phosphonite; thio compounds such as dilaurylthiodipropionate, dimyristylthiodipropionate, and distearylthiodipropionate; various siloxanes; polymerized 2,2,4-trimethyl-1,2-dihydroquinoline, n,n′-bis(1,4-dimethylpentyl-p-phenylenediamine), alkylated diphenylamines, 4,4′ bis(alpha, alpha-dimethylbenzyl)diphenylamine, diphenyl-p-phenylenediamine, mixed diaryl-p-phenylenediamines, and other hindered amine anti-degradants or stabilizers.

The amount of component (E) is not limited, but it is desirably 0.01 mass % or more, 0.05 mass % or more, even 0.1 mass % or more while at the same time is typically 1.0 mass % or less, 0.5 mass % or less, even 0.2 mass % or less based on the mass of the present thermal interface material. This is because when the content of component (E) is equal to or greater than the lower limit of the range described above, stability of component (A) in the present thermal interface material is good, whereas when the content of component (E) is equal to or less than the upper limit of the range described above, mechanical properties of the present thermal interface material are good.

The present material may further comprise (F) a filler-to-polymer interaction promoter. Component (F) is preferably at least one filler-to-polymer interaction promoter selected from a liquid polybutadiene, a silane grafted polyolefin, a silane functionalized polyolefin obtained by reaction of maleinized polyolefin, or a bis(trialkoxysilylalkyl)amine. Exemplary liquid polybutadienes for component (F) include butadiene homopolymer, butadiene-styrene copolymer, and maleinized polybutadiene. An exemplary commercially available liquid polybutadiene is Ricon® 130MA8, available from TOTAL Cray Valley.

The amount of component (F) is not limited, but it is desirably 0.1 mass % or more, 0.5 mass % or more, even 1.0 mass % or more while at the same time is typically 3.0 mass % or less, 2.5 mass % or less, even 2.0 mass % or less based on the mass of the present thermal interface material. This is because when the content of component (F) is equal to or greater than the lower limit of the range described above, stability of component (A) in the present thermal interface material is good, whereas when the content of component (F) is equal to or less than the upper limit of the range described above, mechanical properties of the present thermal interface material are good.

The present material may further comprise (G) a solvent. Exemplary solvents for component (G) include aliphatic hydrocarbon solvents such as toluene, xylene, p-xylene, m-xylene, mesitylene, solvent naphtha H, solvent naphtha A, Isopar H and other paraffin oils and isoparaffinic fluids; alkanes such as pentane, hexane, isohexane, heptane, nonane, octane, dodecane, 2-methylbutane, hexadecane, tridecane, pentadecane, cyclopentane, 2,2,4-trimethylpentane; and siloxane oligomer. An exemplary commercially available siloxane oligomer is DOWSIL™ OS-20, available from Dow Silicones Corporation.

The amount of component (G) is not limited, but it is desirably 0.1 mass % or more, 0.5 mass % or more, 1.0 mass % or more, 1.5 mass % or more, even 2.0 mass % or more while at the same time is typically 5.0 mass % or less, 3.0 mass % or less, even 2.5 mass % or less based on the mass of the present thermal interface material. This is because when the content of component (G) is equal to or greater than the lower limit of the range described above, stability of component (A) in the present material is good, whereas when the content of component (G) is equal to or less than the upper limit of the range described above, mechanical properties of the present material are good.

The present thermal interface material may further comprise additional components such as one or more additives. Such additives include, but are not limited to, antistatic agents, color enhancers, dyes, lubricants, fillers such as TiO₂ or CaCO₃, opacifiers, nucleators, pigments, processing aids, UV stabilizers, anti-blocks, slip agents, tackifiers, fire retardants, anti-microbial agents, odor reducer agents, anti-fungal agents, and combinations thereof.

The present thermal interface material can be prepared by combining all of ingredients at ambient temperature. Any of the mixing techniques and devices described in the prior art can be used for this purpose. The particular device used will be determined by the viscosity of the ingredients and the final composition. Cooling of the ingredients during mixing may be desirable to avoid premature curing.

The present thermal interface material can be applied as a film which is die-cut to an appropriate shape and applied directly on an IC or a heat sink prior to assembly. Conversely, the present thermal interface material can be printed on a component as a thermal grease or compound for stencil or screen printing.

### EXAMPLES

The thermal interface material of the present invention will be described in detail hereinafter using Practical Examples and Comparative Examples. However, the present invention is not limited by the description of the below listed Practical Examples.

### Thermal Impedance (TI) and Bond Line Thickness (BLT) Test

Thermal impedance (TI) and bond line thickness (BLT) were evaluated by means of LW-9389 TIM Thermal Resistance and Conductivity Measurement Apparatus manufactured by LonGwin according to ASTM D-5470 standard. The pressure applied onto the thermal interface material is 40 PSI. The testing time is 15 mins. for one sample. The temperature is 80° C.

### Thermal Testing Vehicle (TTV) Test

The following computer components are used for testing:
CPU: AMD Ryzen 7 2700X 8-Core;
Motherboard: ASUS TUF X470-PLUS GAMING;
Memory: KINSTON DDR4 2666 8 GB;
Graphics Card: ASUS Radeon RX Vega 64 8 GB Overlocked 2048-Bit HBM2 PCI Express 3.0 HDCP Ready Video Card;
Solid State Drive: Intel SSD 760P Series (256 GB, M.2 80 mm PCIe 3.0 x4, 3D2, TLC;
Monitor: Dell U2417H;
Keyboard: Dell;
Mouse: Dell;
PC Case: Antec P8 ATX;
Power Supply: Antec NEO650W;
KVM: MT-viki HK04.

TTV programming: A GPU power cycling test was used to stress GPU and push it to its absolute limits that reflected reliability of thermal interface material (TIM) as applied on the chipset especially for the monitoring of pump-out issue. This test was built with the goal of causing crashing or overheating to ensure that there is no way that the TIM in question will do that during normal or intensive usage. The power cycling test method was achieved by means of full utilization of its processing power, using all the electrical power available to the card while pushing the cooling and the temperatures as far as they can go.

To set up the power cycling program, the following functional software can be simply downloaded online for free and not limit to one choice.
Stable and intensive graphics card/GPU stress test on Windows platform: FurMark, 3D Mark or Unigine Heaven
GPU Monitor: MSI Afterburner, ASUS GPU Teak II
Fan controller: SpeedFan
AUTOIT to implement program in loop

Power cycling test was carried out by reaching the specified high temp in 2.5 mins. while steadily cooling down GPU in another 2.5 mins. for per cycle with temperature interval of 35-85° C. After stress test, the GPU card was disassembled to detect the degradation of TIM morphology on both side of heatsink and chipset. The graphical analysis software can be further performed to determine the overall amount of missing area which can translate to the pump-out degree of TIM, and the cycle number of 5% area pump out was collected. The example of pump out area calculation was as following:
1) Get pump out pictures:
2) Label the die area (A1) and total pump out area (A2) using software Labelme: Calculate the pump out ratio=100×(A1−A2)/A1%.

### Synthesis Example 1

25 g of a copolymer of ethylene and vinylacetate (trade name: Nexxstar™ Low EVA-00111, commercially available from ExxonMobil; vinylacetate content is 7.5 mass %), and represented by the following general formula:

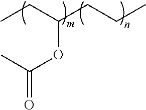

and 300 mL of xylene were added into a 1000 mL round bottom flask, stirred and heated to 130° C. to form a solution, then cooled to 80° C. and 10 g of NaOH was added, the mixture was stirred at 80° C. for 3 hrs., then 10 mL of methanol was added and further stirred at 80° C. for 2.5 hrs., after that, 500 mL of ethanol was added to form the white solid powder. The white powder was filtered and washed with acetone, water, HCl (aq., pH 4) until pH 7, and acetone. The final product was dried under vacuum overnight and structure was confirmed by FTIR as following: EVOH product has no acetate absorption but shows increased OH absorption.

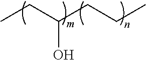

### Synthesis Example 2

20 g of a polybutadiene (trade name: NISSO-PB GI-3000, commercially available from Nippon Soda Co., Ltd.; Mn=3,100; viscosity at 45° C.=31.5 Pa·s; Tg=−37° C.) represented by the following formula:

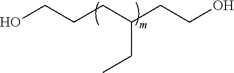

was added into a 100 mL round bottom flask, then 0.01 g of dibutyltin dilaurate and 4.01 g of isocyanic acid octadecyl ester was added under stirring. The final mixture was stirred under 40° C. for 5 hrs. to get the final product. It was confirmed by FTIR that hydroxy groups in the raw polybutadiene were consumed and urethane groups were identified in the final product.

### Practical Examples 1-4 and Comparative Examples 1-4

Thermal interface materials shown in Table 1 were prepared using the components mentioned below.

The following component was used as component (A).

Component (a-1): a polybutadiene represented by the following formula:

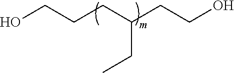

(trade name: NISSO-PB GI-3000, commercially available from Nippon Soda Co., Ltd.; Mn=3,100; viscosity at 45° C.=31.5 Pa·s; Tg=−37 ° C.)
Component (a-2): a polyethylene prepared in Synthesis Example 1.

The following components were used as comparison of component (A).

Component (a-3): a hydrogenated polybutadiene represented by the following formula:

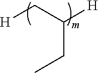

(trade name: NISSO-PB BI-3000, commercially available from Nippon Soda Co., Ltd.; Mn=3,300; viscosity at 45° C.=18.0 Pa·s; Tg=−44 ° C.)
Component (a-4): a polybutadiene represented by the following formula:

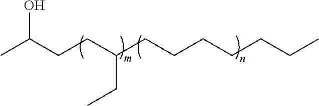

(trade name: Krasol® LBH 5000M, commercially available from Cray Valley Co., Ltd.; Mn=4,500; viscosity at 25° C.=2.5 Pa·s; Tg=−45° C.)
Component (a-5): a polybutadiene prepared in Synthesis Example 2.

The following components were used as component (B).

Component (b-1): zinc oxide filler having an average particle diameter of 0.2 μm (trade name: ZOCO 102, commercially available from Zochem LLC)
Component (b-2): spherical aluminum filler having an average particle diameter of 2 μm (trade name: TCP-02, commercially available from TOYO ALUMINUM K. K.)
Component (b-3): spherical aluminum filler having an average particle diameter of 9 μm (trade name: TCP-09, commercially available from TOYO ALUMINUM K. K.)

The following components were used as component (C).

Component (c-1): octadecane (Melting point=about 28° C.)
Component (c-2): hexatriacontane (Melting point=75-78° C.)
Component (c-3): 1-eicosanol (Melting point=64-66° C.)
Component (c-4): 1,2-tetradecanediol (Melting point=about 67° C.)
Component (c-5): paraffin wax (Melting point=52-54° C.)

The following component was used as component (D).

Component (d-1): n-decyl trimethoxysilane

The following component was used as component (E).

Component (e-1): a hindered phenolic antioxidant (trade name: Irganox® 1010, commercially available from BASF)

TABLE 1

| | | | Category | | | |
|---|---|---|---|---|---|---|
| | | | Practical Examples | | | |
| Item | | | IE1 | IE2 | IE3 | IE4 |
| Composition | (A) | (a-1) | 63.71 | 63.71 | 63.71 | 61.97 |
| of Thermal | | (a-2) | 0 | 0 | 0 | 1.74 |
| Interface | | (a-3) | 0 | 0 | 0 | 0 |
| Material | | (a-4) | 0 | 0 | 0 | 0 |
| (parts by mass) | | (a-5) | 0 | 0 | 0 | 0 |
| | (B) | (b-1) | 173.7 | 173.7 | 173.7 | 173.7 |
| | | (b-2) | 251.2 | 251.2 | 251.2 | 251.2 |
| | | (b-3) | 502.5 | 502.5 | 502.5 | 502.5 |
| | (C) | (c-1) | 0.75 | 0 | 0 | 0 |
| | | (c-2) | 1.50 | 0 | 0 | 0 |
| | | (c-3) | 0 | 0 | 2.25 | 0 |
| | | (c-4) | 0 | 2.25 | 0 | 2.25 |
| | (D) | (d-1) | 6.49 | 6.49 | 6.49 | 6.49 |
| | (E) | (e-1) | 0.15 | 0.15 | 0.15 | 0.15 |

| | | | | |
|---|---|---|---|---|
| Total content of component (A) (mass %) | 6.37 | 6.37 | 6.37 | 6.20 |
| Total content of component (B) (mass %) | 92.74 | 92.74 | 92.74 | 92.74 |
| Total content of component (C) (mass %) | 0.22 | 0.22 | 0.22 | 0.22 |
| Total content of component (D) (mass %) | 0.65 | 0.65 | 0.65 | 0.65 |
| TI (° C. · cm²/W) | 0.071 | 0.048 | 0.051 | 0.078 |
| BLT (μm, 40 PSI, 80° C., 15 mins.) | <20 | <20 | <20 | <20 |
| Number of TTV Cycle leads to 5% area pump out | 6858 | 10025 | 10364 | 9303 |

| | | | Category | | | |
|---|---|---|---|---|---|---|
| | | | Comparative Examples | | | |
| Item | | | CE1 | CE2 | CE3 | CE4 |
| Composition | (A) | (a-1) | 0 | 0 | 0 | 65.96 |
| of Thermal | | (a-2) | 0 | 0 | 0 | 0 |
| Interface | | (a-3) | 63.71 | 0 | 0 | 0 |
| Material | | (a-4) | 0 | 63.71 | 0 | 0 |
| (parts by mass) | | (a-5) | 0 | 0 | 63.71 | 0 |
| | (B) | (b-1) | 173.7 | 173.7 | 173.7 | 173.7 |
| | | (b-2) | 251.2 | 251.2 | 251.2 | 251.2 |
| | | (b-3) | 502.5 | 502.5 | 502.5 | 502.5 |
| | (C) | (c-1) | 0.75 | 0.75 | 0.75 | 0 |
| | | (c-2) | 1.50 | 1.50 | 1.50 | 0 |
| | | (c-3) | 0 | 0 | 0 | 0 |
| | | (c-4) | 0 | 0 | 0 | 0 |
| | (D) | (d-1) | 6.49 | 6.49 | 6.49 | 6.49 |
| | (E) | (e-1) | 0.15 | 0.15 | 0.15 | 0.15 |

| | | | | |
|---|---|---|---|---|
| Total content of component (A) (mass %) | 6.37 | 6.37 | 6.37 | 6.60 |
| Total content of component (B) (mass %) | 92.74 | 92.74 | 92.74 | 92.74 |
| Total content of component (C) (mass %) | 0.22 | 0.22 | 0.22 | 0 |
| Total content of component (D) (mass %) | 0.65 | 0.65 | 0.65 | 0.65 |
| TI (° C. · cm²/W) | 0.068 | 0.076 | 0.088 | 0.075 |
| BLT (μm, 40 PSI, 80° C., 15 mins.) | <20 | <20 | 26 | <20 |
| Number of TTV Cycle leads to 5% area pump out | 378 | 340 | 1795 | 2272 |

### Practical Examples 5-7 and Comparative Examples 5-9

Thermal interface materials shown in Table 2 were prepared using the components mentioned above and the components mentioned below.

The following components were used as component (F).

Component (f-1): a liquid polybutadiene adducted with maleic anhydride having a viscosity at 25° C. of 6,500 mPa·s (trade name: Ricon® 130MA8, commercially available from Cray Valley)
Component (f-2): bis(trimethoxysilylpropyl) amine

The following component was used as component (G).

Component (g-1): siloxane oligomer (trade name: DOWSIL™ OS-20, commercially available from Dow Silicones Corporation)

TABLE 2

| | | | Category | | | |
|---|---|---|---|---|---|---|
| | | | | | | Comp. |
| | | | Practical Examples | | | Example |
| Item | | | IE5 | IE6 | IE7 | CE5 |
| Composition | (A) | (a-1) | 61.46 | 61.32 | 61.32 | 0 |
| of Thermal | | (a-3) | 0 | 0 | 0 | 63.71 |
| Interface | | (a-4) | 0 | 0 | 0 | 0 |
| Material | | (a-5) | 0 | 0 | 0 | 0 |
| (parts by mass) | (B) | (b-1) | 173.7 | 173.7 | 173.7 | 173.7 |
| | | (b-2) | 251.2 | 251.2 | 251.2 | 251.2 |
| | | (b-3) | 502.5 | 502.5 | 502.5 | 502.5 |
| | (C) | (c-1) | 0 | 0 | 0 | 0 |
| | | (c-2) | 0 | 0 | 0 | 0 |
| | | (c-3) | 4.50 | 2.25 | 2.25 | 2.25 |
| | (D) | (d-1) | 6.49 | 6.49 | 6.49 | 6.49 |
| | (E) | (e-1) | 0.15 | 0.15 | 0.15 | 0.15 |
| | (F) | (f-1) | 0 | 1.96 | 1.96 | 0 |
| | | (f-2) | 0 | 0.43 | 0.43 | 0 |
| | (G) | (g-1) | 0 | 0 | 23.0 | 0 |

| | | | | |
|---|---|---|---|---|
| Total content of component (A) (mass %) | 6.15 | 6.13 | 5.99 | 6.37 |
| Total content of component (B) (mass %) | 92.74 | 92.74 | 90.65 | 92.74 |
| Total content of component (C) (mass %) | 0.45 | 0.22 | 0.22 | 0.22 |
| Total content of component (D) (mass %) | 0.65 | 0.65 | 0.63 | 0.65 |
| Total content of component (E) (mass %) | 0 | 0.24 | 0.23 | 0 |
| TI (° C. · cm²/W) | 0.063 | 0.065 | 0.068 | 0.071 |
| BLT (μm, 40 PSI, 80° C., 15 mins.) | <20 | <20 | <20 | <20 |
| Number of TTV Cycle leads to 5% area pump out | 5046 | >11758 | >11067 | 437 |

| | | | Category | | | |
|---|---|---|---|---|---|---|
| | | | Comparative Example | | | |
| Item | | | CE6 | CE7 | CE8 | CE9 |
| Composition | (A) | (a-1) | 0 | 0 | 56.96 | 68.13 |
| of Thermal | | (a-3) | 0 | 0 | 0 | 0 |
| Interface | | (a-4) | 63.71 | 0 | 0 | 0 |
| Material | | (a-5) | 0 | 63.71 | 0 | 0 |
| (parts by mass) | (B) | (b-1) | 173.7 | 173.7 | 173.7 | 173.7 |
| | | (b-2) | 251.2 | 251.2 | 251.2 | 251.2 |
| | | (b-3) | 502.5 | 502.5 | 502.5 | 502.5 |
| | (C) | (c-1) | 0 | 0 | 0 | 0.75 |
| | | (c-2) | 0 | 0 | 0 | 1.50 |
| | | (c-3) | 2.25 | 2.25 | 9.00 | 2.25 |
| | (D) | (d-1) | 6.49 | 6.49 | 6.49 | 0 |
| | (E) | (e-1) | 0.15 | 0.15 | 0.15 | 0.15 |
| | (F) | (f-1) | 0 | 0 | 0 | 1.70 |
| | | (f-2) | 0 | 0 | 0 | 0.37 |
| | (G) | (g-1) | 0 | 0 | 0 | 0 |

| | | | | |
|---|---|---|---|---|
| Total content of component (A) (mass %) | 6.37 | 6.37 | 5.70 | 6.81 |
| Total content of component (B) (mass %) | 92.74 | 92.74 | 92.74 | 92.74 |
| Total content of component (C) (mass %) | 0.45 | 0.22 | 0.90 | 0.22 |
| Total content of component (D) (mass %) | 0.65 | 0.65 | 0.63 | 0 |
| Total content of component (E) (mass %) | 0 | 0 | 0 | 0.21 |
| TI (° C. · cm²/W) | 0.092 | 0.096 | 0.065 | 0.217 |
| BLT (μm, 40 PSI, 80° C., 15 mins.) | <20 | <20 | <20 | 29 |
| Number of TTV Cycle leads to 5% area pump out | 1696 | 2253 | 1333 | — |

According to the results in Tables 1 and 2, it was confirmed that hydroxyl groups in the polyolefin for component (A) were important for prevent pump out, since comparative thermal interface materials (CE1, CE2, CE5 and CE6) had poor anti-pump out in comparison with the present thermal interface materials (IE1, IE3 and IE4). The treatment (capping) of hydroxyl with isocyanic acid octadecyl ester also confirmed this finding, since comparative thermal interface materials (CE3 and CE7) were poor in preventing pump out compared with the present thermal interface materials (IE1 and IE3). The appropriate loading of the phase change materials for component (B), especially the hydroxyl group-containing hydrocarbon wax, is helping to improve the thermal conductivity and preventing pump out, as comparative thermal interface material (CE4) showed poor anti-pump out performance and higher TI compare with the present thermal interface materials (IE1, IE2 and IE3).

However, the high loading of phase change material (is this the same as the phase change material will hurt the anti-pump out performance, because 0.45 mass % of phase change material (IE5) just meet the passing criteria while 0.9 mass % of phase change material (CE8) failed. The coupling agent is also needed, as comparative thermal interface material (CE9) showed much higher TI than the present thermal interface materials (IE1 and IE6), and can't be used for TTV testing. The significance is introducing of a filler-to-polymer interaction promoter for component (F) interaction promotor will further improve the anti-pump out performance of the present thermal interface material (IE6), and introducing of a solvent for component (G) will enable the formulation grease like instead of pad (IE7).

### Comparative Examples 10-15

Thermal interface materials shown in Table 3 were prepared using the components mentioned above and the components mentioned below.

The following component was further used as component (A).

Component (a-6): a polybutadiene represented by the following formula:

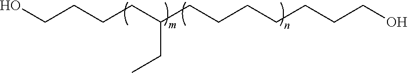

(trade name: Krasol® H-LBH P 3000, commercially available from Cray Valley Co., Ltd.; Mn=3,000; viscosity at 25° C.=1.5 Pa·s; Tg=−45 ° C.)

The following component was further used as component (D).

Component (d-2): isopropyl tri(dioctylpyrophosphate) titanate

The following component was used as component (H) for a crosslinker.

Component (h-1): a methylated melamine-formaldehyde resin (trade name: CYMEL® 325 resin, commercially available from CYTEC Industries Inc.)

The following component was used as component (I) for a catalyst.

Component (i-1): a sulfonic acid (trade name: NACURE® 155, commercially available from King Industries Inc.)

TABLE 3

| | | | Category | | | |
|---|---|---|---|---|---|---|
| | | | Comparative Examples | | | |
| Item | | | CE10 | CE11 | CE12 | CE13 |
| Composition | (A) | (a-1) | 0 | 0 | 53.92 | 0 |
| of Thermal | | (a-6) | 51.45 | 47.47 | 0 | 61.41 |
| Interface | (B) | (b-1) | 173.7 | 173.7 | 173.7 | 173.7 |
| Material | | (b-2) | 251.2 | 251.2 | 251.2 | 251.2 |
| (parts by mass) | | (b-3) | 502.5 | 502.5 | 502.5 | 502.5 |
| | (C) | (c-1) | 5.37 | 5.00 | 1.22 | 0.75 |
| | | (c-2) | 0 | 0 | 0 | 1.50 |
| | | (c-5) | 9.14 | 8.44 | 2.23 | 0 |
| | (D) | (d-1) | 6.49 | 6.49 | 6.49 | 0 |
| | | (d-2) | 0 | 0 | 0 | 6.49 |
| | (E) | (e-1) | 0.15 | 0.15 | 0.15 | 0.15 |
| | (F) | (f-1) | 0 | 0 | 0 | 0 |
| | | (f-2) | 0 | 0 | 0 | 0 |
| | (H) | (h-1) | 0 | 4.59 | 7.81 | 2.30 |
| | (I) | (i-1) | 0 | 0.46 | 0.78 | 0 |

| | | | | |
|---|---|---|---|---|
| Total content of component (A) (mass %) | 5.15 | 4.75 | 5.39 | 6.14 |
| Total content of component (B) (mass %) | 92.74 | 92.74 | 92.74 | 92.74 |
| Total content of component (C) (mass %) | 1.45 | 1.34 | 0.35 | 0.23 |
| Total content of component (D) (mass %) | 0.65 | 0.65 | 0.65 | 0.65 |
| Total content of component (E) (mass %) | 0 | 0 | 0 | 0 |
| TI (° C. · cm²/W) | 0.053 | 0.074 | 0.075 | 0.071 |
| BLT (μm, 40 PSI, 80° C., 15 mins.) | <20 | <20 | <20 | <20 |
| Number of TTV Cycle leads to 5% area pump out | 657 | 218 | 102 | 118 |

| | | | Category | |
|---|---|---|---|---|
| | | | Comparative | |
| | | | Examples | |
| Item | | | CE14 | CE15 |
| Composition | (A) | (a-1) | 62.16 | 46.22 |
| of Thermal | | (a-6) | 0 | 0 |
| Interface | (B) | (b-1) | 173.7 | 173.7 |
| Material | | (b-2) | 251.2 | 251.2 |
| (parts by mass) | | (b-3) | 502.5 | 502.5 |
| | (C) | (c-1) | 0.75 | 0 |
| | | (c-2) | 1.50 | 0 |
| | | (c-5) | 0 | 14.30 |
| | (D) | (d-1) | 6.49 | 6.49 |
| | | (d-2) | 0 | 0 |
| | (E) | (e-1) | 0.15 | 0.15 |
| | (F) | (f-1) | 1.55 | 4.47 |
| | | (f-2) | 0 | 0.98 |
| | (H) | (h-1) | 0 | 0 |
| | (I) | (i-1) | 0 | 0 |

| | | |
|---|---|---|
| Total content of component (A) (mass %) | 6.22 | 4.62 |
| Total content of component (B) (mass %) | 92.74 | 92.74 |
| Total content of component (C) (mass %) | 0.23 | 1.43 |
| Total content of component (D) (mass %) | 0.65 | 0.65 |
| Total content of component (E) (mass %) | 0 | 0.54 |
| TI (° C. · cm²/W) | 0.053 | 0.106 |
| BLT (μm, 40 PSI, 80° C., 15 mins.) | <20 | 30 |
| Number of TTV Cycle leads to 5% area pump out | 2057 | — |

According to the results in Table 3, it was confirmed that the other comparative thermal interface materials from prior arts (CE10-CE14) showed poor anti-pump out performance. And over loading of the filler-to-polymer interaction promotor for component (F) will hurt the TI performance (CE15). Therefore, the present thermal interface materials showed more promising in TIM application.

### INDUSTRIAL APPLICABILITY

The thremal interface material of the present invention becomes softer as its temperature increases, while does not exhibit pumping-out in electronic devices during power cycling. Therefore, the thermal interface material is useful for a thermal coupling material to transfer heat from heat generating electronic components such as central processing units (CPU), or graphic processing units (GPU) to heat spreader such as heat sink.

1. A thermal interface material comprising:
(A) a polyolefin having at least two hydroxy groups per molecule;
(B) at least one thermally conductive filler;
(C) a phase change material with a melting point of 25 to 150° C.; and
(D) a coupling agent,
wherein a content of component (B) is at least 80 mass %, a content of component (C) is 0.01 to 1 mass %, and a content of component (D) is 0.1 to 1 mass %, each based on a total mass of the thermal interface material.

2. The thermal interface material according to claim 1, wherein component (A) is a polyolefin represented by the following general formula: 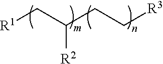
wherein each R¹, R² and R³ is independently a hydrogen atom, a hydroxy group or an alkyl group with 1 to 12 carbons, provided that at least two of a total R¹ to R³ are hydroxy groups; and “m” is a positive number, “n” is 0 or a positive number, provided that “m+n” is a positive number satisfying a number average molecular weight of 2,000 to 100,000 as measured by a gel permeation chromatography.

3. The thermal interface material according to claim 1, wherein component (B) is at least one thermally conductive filler selected from the group consisting of alumina, aluminum, zinc oxide, boron nitride, aluminum nitride, and aluminum oxide trihydrate.

4. The thermal interface material according to claim 1, wherein component (C) is at least one phase change material selected from the group consisting of C₁₂-C₂₅ alcohols, C₁₂-C₂₅ acids, C₁₂-C₂₅ esters, waxes, and combinations thereof.

5. The thermal interface material according to claim 1, wherein component (D) is at least one coupling agent selected from the group consisting of a silicon-based coupling agent, a titanium-based coupling agent, and an aluminum-based coupling agent.

6. The thermal interface material according to claim 5, wherein component (D) is a silicon-based coupling agent represented by the following general formula:
R⁴ₐR⁵_{b}Si(OR⁶)_{(4-a-b)}
wherein each R⁴ is independently an alkyl group with 6 to 15 carbons, each R⁵ is independently an alkyl group with 1 to 5 carbons or an alkenyl groups with 2 to 6 carbons, each R⁶ is independently an alkyl group with 1 to 4 carbons; and “a” is an integer of 1 to 3, “b” is an integer of 0 to 2, provided that “a+b” is an integer of 1 to 3.

7. The thermal interface material according to claim 1, further comprising:
(E) an antioxidant.

8. The thermal interface material according to claim 1, further comprising:
(F) a filler-to-polymer interaction promoter.

9. The thermal interface material according to claim 8, wherein component (F) is at least one filler-to-polymer interaction promoter selected from the group consisting of a liquid polybutadiene, a silane grafted polyolefin, and a bis(trialkoxysilylalkyl)amine.

10. The thermal interface material according to claim 1, further comprising:
(G) a solvent.

11. The thermal interface material according to claim 7, further comprising:
(F) a filler-to-polymer interaction promoter.

12. The thermal interface material according to claim 11, further comprising:
(G) a solvent.
